(19) United States
(12) Patent Application Publication
(10) Pub. No.: US 2023/0023894 A1
(43) Pub. Date: Jan. 26, 2023

(54) THERMAL REGULATION DEVICE AND CORRESPONDING ASSEMBLY METHOD

(71) Applicant: VALEO SYSTEMES THERMIQUES, La Verriere (FR)

(72) Inventors: Boris BARRE, La Verriere (FR); Anne-Sophie MIZRAHI, La Verriere (FR); Jean Damien MULLER, La Verriere (FR); Jean Christophe PREVOST, La Verriere (FR); Frederic TISON, La Verriere (FR)

(73) Assignee: VALEO SYSTEMES THERMIQUES, La Verriere (FR)

(21) Appl. No.: 17/787,473

(22) PCT Filed: Dec. 7, 2020
(86) PCT No.: PCT/FR2020/052307

§ 371 Date: Jun. 20, 2022

(30) Foreign Application Priority Data
Dec. 20, 2019 (FR) 1915330

(51) Int. Cl. H01M 10/6557; H05K 7/20; H01M 10/613; H01M 10/625; H01M 10/6555; H01M 10/6568

(52) U.S. Cl. CPC H01M 10/6557; H05K 7/20272; H01M 10/613; H01M 10/625; H01M 10/6555; H01M 10/6568; H01M 2220/20

(57) ABSTRACT

The invention relates to a thermal regulation device for at least one electronic and/or electrical component, in particular for a motor vehicle, having a stack of at least two pairs of plates, defining circulation channels for heat-transfer fluid, and at least one heat-transfer fluid manifold, in fluidic communication with the circulation channels for heat-transfer fluid. The at least one heat-transfer fluid manifold has at least two complementary hollow manifolds. Each manifold is joined to an associated pair of plates and includes a distribution zone having at least one slot leading into the circulation channel for heat-transfer fluid. The manifolds joined to two adjacent pairs of plates have a male part and a complementary female part that are fitted one in the other, the male part bearing at least one seal. The invention also relates to a corresponding method for assembling such a device.

### CROSS-REFERENCE TO RELATED APPLICATIONS

This application is filed under 35 U.S.C. § 371 U.S. National Phase of International Application No. PCT/FR2020/052307 filed Dec. 7, 2020 (published as WO2021123550), which claims priority benefit to French application No. 1915330 filed on Dec. 20, 2019, the disclosures of which are herein incorporated by reference in their entirety.

### TECHNICAL FIELD

The present invention relates to a device for thermal regulation of electrical and/or electronic components liable to release heat during operation, these components being in particular electrical energy storage elements or a power electronics device, in particular in the automotive field. The invention also relates to a method for assembling such a thermal regulation device.

### BACKGROUND OF THE INVENTION

The invention is advantageously applicable in the field of devices for thermal regulation of a power electronics device or module, i.e. comprising power electronics components, such as, purely by way of example, semi-conductors, such as diodes or transistors. In operation, the temperature of such a power electronics device or module may rise, with the risk of damage to some of the power electronics components.

The invention is also advantageously applicable in the field of devices for thermal regulation of electrical energy storage elements, such as batteries of electrically-powered and/or hybrid-powered motor vehicles. The electrical energy for electrically-powered and/or hybrid-powered motor vehicles is supplied by one or more batteries. During operation, electrical energy storage elements such as batteries are caused to heat up and thus risk being damaged.

One charging technique, referred to as rapid charging, consists in charging the energy storage elements at a high voltage and amperage, over a short time, in particular a maximum time of about twenty minutes. Such rapid charging causes the electrical energy storage elements to heat up significantly, something which needs to be managed.

For thermal regulation, in particular cooling, of electrical energy storage elements, such as batteries, it is known practice to use a thermal regulation device.

According to one known solution, the thermal regulation device comprises cooling plates incorporating circulation channels for a heat transfer fluid, such as a coolant liquid, arranged between the electrical energy storage elements.

The plates are brazed together and usually also brazed to coolant liquid inlet and outlet manifolds to ensure sealing. In particular, during assembly, such electrical energy storage elements for example and the pairs of plates are stacked successively. However, such an assembly does not offer any flexibility with regard to the insertion of the energy storage elements to be cooled in the thermal regulation device.

Another problem is to ensure an adequate flow rate of heat transfer fluid in each pair of plates, in particular in the intermediate pairs which are arranged between two faces of components to be thermally regulated, and the end pairs which are only arranged against one face of a component to be thermally regulated.

### BRIEF SUMMARY OF THE INVENTION

The aim of the invention is to at least partially overcome these problems encountered in the prior art by allowing better insertion into the thermal regulation device of electrical and/or electronic components, such as energy storage elements to be cooled, while ensuring effective cooling of electrical and/or electronic components liable to release heat during operation.

Another aim is to optimize the flow rate of heat transfer fluid between the pairs of plates.

To this end, the subject matter of the invention is a thermal regulation device for at least one electronic and/or electrical component, in particular for a motor vehicle, said device comprising:

a. a stack of at least two pairs of plates, said at least one component being intended to be arranged between the two pairs of plates, the plates defining in pairs a heat transfer fluid circulation channel, and

b. at least one heat transfer fluid manifold, in fluidic communication with the heat transfer fluid circulation channels defined by the pairs of plates.

According to the invention, said at least one heat transfer fluid manifold comprises at least two complementary hollow connectors. Each connector is assembled to an associated pair of plates and comprises a distribution zone having at least one slot opening into the heat transfer fluid circulation channel defined by the pair of plates. The connectors assembled to two adjacent pairs of plates comprise complementary male and female parts, fitted one inside the other, the male part bearing at least one seal.

The connectors, each assembled to an associated pair of plates, can be mechanically assembled together by being fitted one inside the another, which offers flexibility of assembly when inserting components between the pairs of plates. Moreover, this prevents damage to the fluidic connection areas of the plates.

The thermal regulation device can also have one or more of the following features described below, considered separately or in combination.

The stack of at least two pairs of plates has two end plates.

Said at least one seal is for example made of elastomer.

The function of sealing is not intended to be ensured by brazing. The function of sealing is ensured by the seal or seals added and assembled to the thermal regulation device. The mechanical connection between the connectors is not irreversible. Said at least one seal is not intended to melt to ensure sealing.

The connectors are for example of generally tubular or cylindrical shape.

According to one aspect, said at least one heat transfer fluid manifold comprises a predefined number of complementary hollow connectors, including two end connectors.

Said at least one heat transfer fluid manifold can include at least one intermediate connector between the two end connectors.

The end connectors include a first end connector comprising a male part and a second end connector comprising a female part.

One of the end connectors is configured to be connected to a heat transfer fluid circuit.

The other end connector is closed off on a side opposite the stack of plates.

According to a preferred embodiment, one of the end connectors has a connection member for connection to the heat transfer fluid circuit.

The other end connector can have a blind wall closing off an opening in an end plate.

The connection member can have a generally cylindrical shape extending from an end plate on the opposite side to the stack of plates.

According to one particular embodiment, said thermal regulation device comprises two manifolds for the entry and for the exit of heat transfer fluid. Each manifold has at least two end connectors as defined above.

According to another aspect, said thermal regulation device comprises at least one pair of intermediate plates between two end plates.

The pair of intermediate plates is assembled with an intermediate connector comprising on one side a male part and on the other side a female part.

Advantageously, the male parts of the connectors are identical.

Likewise, the female parts of the connectors are identical.

According to an exemplary embodiment, the male parts of the connectors have at least one groove in which said at least one seal is arranged.

According to yet another aspect, the plates are arranged along a stacking axis and the complementary male and female parts of the connectors are fitted one inside the other along the stacking axis.

Preferably, the connectors are fitted together with an axial clearance between the end of the female part and the end of the male part.

The connectors can slide one inside the other during the interposition of a component between two pairs of plates, so as to make it possible to compress the pairs of plates and the component or components after assembly.

According to an exemplary embodiment, the connectors respectively have at least two slots opening into the heat transfer fluid circulation channel defined by the associated pair of plates.

The two slots on each connector are configured to allow the fluid to be distributed with a similar flow rate allowing all the components to be cooled in the same way.

The two slots can be dimensioned such that the ratio of the total section for passage of the heat transfer fluid through the two slots in the connector to the section for passage of the heat transfer fluid in the heat transfer fluid manifold is between 12% and 25%, in particular between 16% and 21%. This makes it possible to ensure a correct balance of heat transfer fluid in the various plates, depending on the number of plates.

When the connectors are generally cylindrical in shape, the slots can extend over a circumference of the distribution zone over a cumulative angle between 30° and 180°.

Advantageously, the male part of a connector bears at least two seals.

Alternatively, a seal with at least two lips can be provided on each male part.

The seal or seals have a shape complementary to the male part of the connector, for example an O-ring shape.

According to another aspect, the connectors respectively have a flange. The connector flanges make assembly easier.

The flange can have a poka-yoke surface. This ensures that the connectors are mounted in a specific position.

According to one embodiment, the plates each have at least one opening, and the connectors are assembled to the pairs of plates such that the distribution zone of each connector is arranged at the openings in the plates of an associated pair.

According to the embodiment described, each plate has two openings.

The two openings can be in the same fluidic connection region.

The plates advantageously comprise a collar bordering at least one, preferably each opening.

According to one aspect, the plates and the connectors are metal. Each pair of plates can be assembled by brazing to at least one connector, preferably to two connectors.

The invention also relates to a method for assembling a thermal regulation device as claimed in one of the preceding claims, comprising the following steps:

a. assembling at least two pairs of plates defining between them a heat transfer fluid circulation channel,

b. assembling at least a first connector to a first associated pair of plates and a second connector to a second associated pair of plates, such that said at least one slot in the distribution zone of each connector opens into the heat transfer fluid circulation channel defined by the associated pair of plates,

c. arranging at least one seal on the male part of at least one of the connectors, and

d. assembling the connectors by fitting together the male and female parts of the connectors of the adjacent pairs of plates.

A thermal regulation device thus assembled can be delivered to a manufacturer for assembly of the component or components between the pairs of plates.

The connector or connectors are assembled to an associated pair of plates by brazing.

The method does not include a step of brazing the whole of said thermal regulation device.

The connector assembly step is therefore a mechanical assembly step. Such a mechanical assembly step can be carried out at ambient temperature, unlike a step of assembly by brazing involving passing through a furnace.

### BRIEF DESCRIPTION OF THE DRAWINGS

Further advantages and features of the invention will become more clearly apparent from reading the following description, given by way of illustrative and non-limiting example, and the appended drawings, in which:

FIG. 1 is a perspective view of a thermal regulation device comprising a stack of pairs of plates and two heat transfer fluid manifolds.

FIG. 2 is a perspective view of a plate of the thermal regulation device of FIG. 1,

FIG. 3 shows in more detail a fluidic connection area of the plate of FIG. 2,

FIG. 4 is an exploded view of a thermal regulation sub-assembly comprising a pair of plates, two connectors and seals, before assembly,

FIG. 5 is a perspective view of the thermal regulation sub-assembly of FIG. 4 in an assembled form,

FIG. 6 is an enlarged view of one end of the stack of the thermal regulation device of FIG. 1,

FIG. 7 is an enlarged view of the other end of the stack of the thermal regulation device of FIG. 1,

FIG. 8 shows an embodiment of an intermediate connector of at least one heat transfer fluid manifold of FIG. 1,

FIG. 9 is a view in partial section showing the intermediate connector of FIG. 8, assembled in the openings in a pair of plates.

FIG. 10 shows two complementary connectors of two thermal regulation sub-assemblies assembled together,

FIG. 11 is a view of a first end connector of a given heat transfer fluid manifold,

FIG. 12 is a view of a second end connector of the given heat transfer fluid manifold,

FIG. 13 is a first view of a first end connector of another heat transfer fluid manifold,

FIG. 14 is a second view of the first end connector of FIG. 13, and

FIG. 15 is a view of a second end connector of the other heat transfer fluid manifold.

### DETAILED DESCRIPTION OF THE INVENTION

In these figures, identical elements bear the same reference numerals.

The following embodiments are examples. Although the description refers to one or more embodiments, this does not necessarily mean that each reference relates to the same embodiment, or that the features apply only to a single embodiment. Individual features of various embodiments can also be combined or interchanged in order to create other embodiments.

In the description, certain elements can be indexed, such as first element or second element, for example. In this case, this is merely indexing for differentiating and denoting elements that are similar but not identical. This indexing does not imply that one element takes priority over another and such denominations can easily be interchanged without departing from the scope of the present description. This indexing does not imply an order in time either.

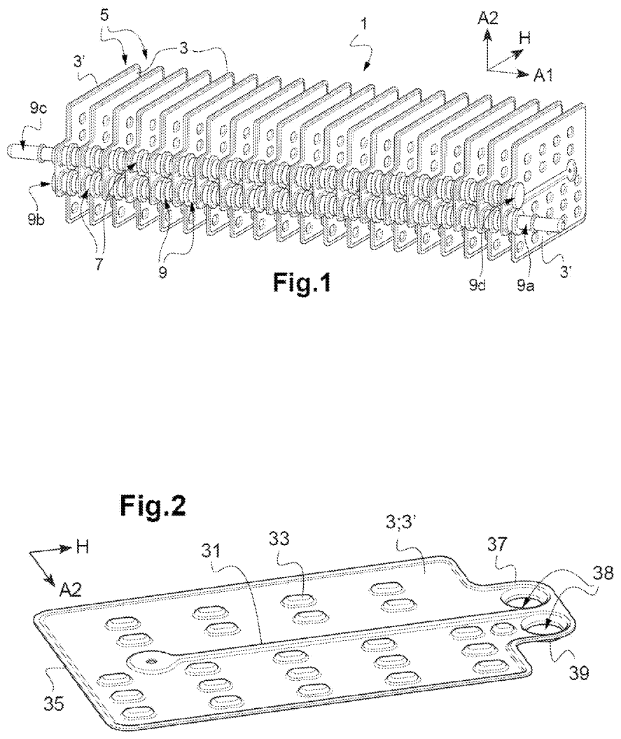

FIG. 1 shows a thermal regulation device 1 intended to receive one or more electronic and/or electrical components (not shown) liable to release heat during operation, for the thermal regulation, in particular cooling, of these components. The components to be thermally regulated are in particular electrical energy storage elements or a power electronics device, in particular in the automotive field. By way of example, they can be electrical cells forming part of a battery pack in an electric or hybrid vehicle.

Such a thermal regulation device 1 is intended in particular to be fitted in a motor vehicle. In general, the thermal regulation device 1 comprises a predefined number of plates 3, 3′, assembled in pairs 5. The pairs 5 of plates 3, 3′ are arranged in at least one row along a stacking axis Al. The plates 3, 3′ comprise two end plates 3′ and a predefined number of intermediate plates 3. The plates 3 define, in pairs 5, at least one heat transfer fluid circulation channel. The thermal regulation device 1 comprises at least two pairs 5 of plates 3, 3′. According to the embodiment shown in FIG. 1, the stack of pairs 5 of plates 3, 3′ comprises a plurality of pairs 5 of intermediate plates 3 between two end pairs 5 along the stacking axis A1.

The electronic and/or electrical components are intended to be interposed between the pairs 5 of plates 3, 3′, so as to form a stack of pairs 5 of plates 3, 3′ and of components along the stacking axis A1. A thermal interface (not shown) can be provided between each electronic and/or electrical component and the adjacent plates 3, 3′ so as to guarantee heat transfer. Alternatively or in addition, at least one electrical insulator (not shown) can be provided between the electronic and/or electrical components and the adjacent plates 3, 3′.

In the example shown, the thermal regulation device 1 has the general shape of a parallelepiped, in particular a rectangular parallelepiped, the longitudinal axis of which is the stacking axis A1, and extends in width along an axis A2 transverse to the stacking axis A1, and in height along an axis H.

The thermal regulation device 1 further comprises at least one heat transfer fluid manifold 7. The heat transfer fluid is for example a coolant liquid. The heat transfer fluid circulation channels defined by the pairs 5 of plates 3, 3′ are arranged in fluidic communication with said at least one heat transfer fluid manifold 7.

In the example shown, the thermal regulation device 1 comprises two manifolds 7 for the entry and for the exit of heat transfer fluid. Each heat transfer fluid manifold 7 extends longitudinally along the stacking axis A1. At least one of the heat transfer fluid manifolds 7 is defined by one or more added parts separate from the plates 3, 3′. As described in more detail below, they are a plurality of complementary hollow connectors 9, 9a, 9b, 9c, 9d.

One of the heat transfer fluid manifolds 7 allows the heat transfer fluid, specifically cold heat transfer fluid, to circulate and be distributed to the various pairs 5 of plates 3, 3′, the other ensures the return of the heat transfer fluid, specifically hot heat transfer fluid, after it passes through the pairs 5 of plates 3. The fluid inlet and outlet can be arranged on two opposite sides of the thermal regulation device 1, such that the heat transfer fluid can generally flow in the thermal regulation device 1 in an “I” circulation. The two heat transfer fluid manifolds 7 are connected to the same side of each plate 3, 3′.

Other flow patterns can be considered, such as “U” circulation with the fluid inlet and outlet arranged on the same side of thermal regulation device 1.

The plates 3, 3′ are preferably made of metal. The plates 3, 3′ can be made from stamped sheet metal. Preferably, the plates 3, 3′ are similar, including the end plates 3′. In this way, the surface for heat exchange with a component is the same regardless of the side of the pair 5 of plates 3, 3′ against which the component is intended to be placed. According to an alternative not shown, the end plates 3′ can be made differently.

In particular, each plate 3 extends in a plane perpendicular to the stacking axis A1. The plates 3, 3′ extend along the transverse axis A2 and the vertical axis H. The plates 3 can have a generally rectangular shape. Purely by way of example, the plates 3, 3′ have two long sides extending along the vertical axis H and two short sides extending along the transverse axis A2.

Moreover, the plates 3 are shaped so as to allow, when they are assembled in pairs 5, the circulation of the heat transfer fluid. In particular, the plates 3, 3′ can each have a substantially hollow or bowl shape, so as to allow the heat transfer fluid to flow between the two plates 3, 3′ of a pair 5 after assembly.

The heat transfer fluid can flow between the plates 3, 3′ of a pair 5 in one or more passes, with a linear or non-linear flow pattern. To this end, the plates 3 can each have at least one rib 31, which can be central as in the example shown in FIG. 2, and the end of which can optionally be rounded. Such a rib 31 is provided on the face, referred to as the internal face, of a plate 3 intended to be arranged facing an associated plate 3 upon assembly of a pair of plates 3. The ribs 31 of the two plates 3 are intended to form a projection in the heat transfer fluid circulation channel in order to define a flow pattern or path or different passes of the heat transfer fluid.

Furthermore, the plates 3, 3′ can have a multitude of bosses 33 on their internal faces presenting the rib or ribs 31, in order to ensure mechanical strength vis-à-vis internal and/or external pressure. The bosses 33 are also intended to form a projection in the heat transfer fluid circulation channel when the two plates 3, 3′ of a pair 5 are assembled.

Each plate 3 can have a peripheral edge 35 over the entire contour of the plate 3. The plates 3, 3′ are joined in pairs such that they are sealed at their respective peripheral edges 35. The plates 3, 3′ are advantageously made of metal and can be connected in a sealed manner, for example by brazing.

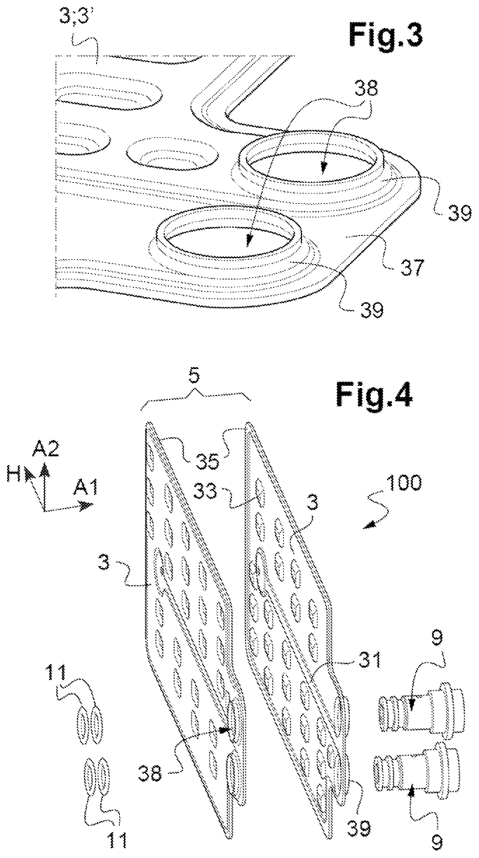

The plates 3, 3′ respectively comprise at least one fluidic connection area 37. According to the embodiment of a plate 3 or 3′ shown in FIG. 2, a single fluidic connection area 37 is formed at a side edge of the plate 3, 3′. The plate 3, 3′ has a heat transfer fluid inlet and outlet defined by two openings 38. In this example, the openings 38 are arranged in the same fluidic connection area 37. The openings 38 are bordered with collars 39 which can be seen more clearly in FIG. 3. The collars 39 are for example generally cylindrical in shape.

With reference to FIGS. 4 to 7, the collars 39 are oriented toward the outside of the heat transfer fluid circulation channel defined between two plates 3, 3′ of the same pair 5. The collars 39 of the intermediate plates 3 extend in the direction of a plate 3 of a neighboring or adjacent pair 5. The collar or collars 39 of an end plate 3′ extend in a direction away from the stack.

The connectors 9, 9a, 9b, 9c, 9d are arranged so as to place the pairs 5 of plates 3, 3′ in fluidic communication. The connectors 9, 9a, 9b, 9c, 9d comprise at least two end connectors 9a, 9b, 9c, 9d and possibly a predefined number of intermediate connectors 9 assembled so as to define at least one heat transfer fluid manifold 7.

According to a minimum configuration of a thermal regulation device 1 with at least two pairs 5 of plates 3, 3′ comprising the end plates 3′, at least the four end connectors 9a, 9b, 9c, 9d are assembled together and to these two pairs 5. Each heat transfer fluid manifold 7 has two end connectors 9a, 9b, respectively 9c, 9d.

If at least one pair 5 of intermediate plates 3 is arranged between the two end pairs 5, the or each heat transfer fluid manifold 7 comprises at least one intermediate connector 9 in addition to the two end connectors 9a, 9b, or 9c, 9d. When several intermediate connectors 9 are provided, they are similar. The end connectors 9a, 9b, 9c, 9d are different from the intermediate connectors 9.

Two end connectors 9a, 9b and any intermediate connectors 9 can be assembled so as to define a first heat transfer fluid manifold 7. Two other end connectors 9c, 9d and any intermediate connectors 9 can be assembled so as to define a second heat transfer fluid manifold 7.

Each connector 9, 9a, 9b, 9c, 9d is assembled to an associated pair 5 of plates 3, 3′, thus forming a thermal regulation sub-assembly 100, or 200, or 300. Furthermore, the connectors 9, 9a, 9b, 9c, 9d are advantageously made of metal, such as aluminum or aluminum alloy.

The assembly of a connector, two connectors 9, 9a, 9b, 9c, 9d in the example described, to an associated pair 5 of plates 3, 3′ can be performed by brazing. A strong sealed connection is thus ensured between the pairs 5 of plates 3, 3′ and the associated connectors 9, 9a, 9b, 9c, 9d.

Each thermal regulation sub-assembly 100, or 200, or 300 is independent with respect to another thermal regulation sub-assembly 100, or 200, or 300. The various sub-assemblies 100, 200, 300 can then be assembled together, which makes it possible to obtain a modular thermal regulation device 1.

According to the embodiment shown, the connectors 9, 9a, 9b, 9c, 9d, are arranged in the openings 38 in the plates 3, 3′. Each connector 9, 9a, 9b, 9c, 9d passes through two facing openings 38 in the two plates 3, 3′ of an associated pair 5.

The connectors 9, 9a, 9b, 9c, 9d have a shape complementary to the shape of the openings 38 advantageously edged with collars 39. According to the embodiment described, the connectors 9, 9a, 9b, 9c, 9d respectively have a generally tubular or cylindrical shape, the axis of revolution of which coincides with the stacking axis A1 when the connectors 9, 9a, 9b, 9c, 9d are assembled with the pairs 5 of plates 3, 3′.

The connectors 9, 9a, 9b, 9c, 9d are shaped such that connectors assembled to two adjacent pairs 5 of plates comprise complementary male and female parts, fitted one inside the other.

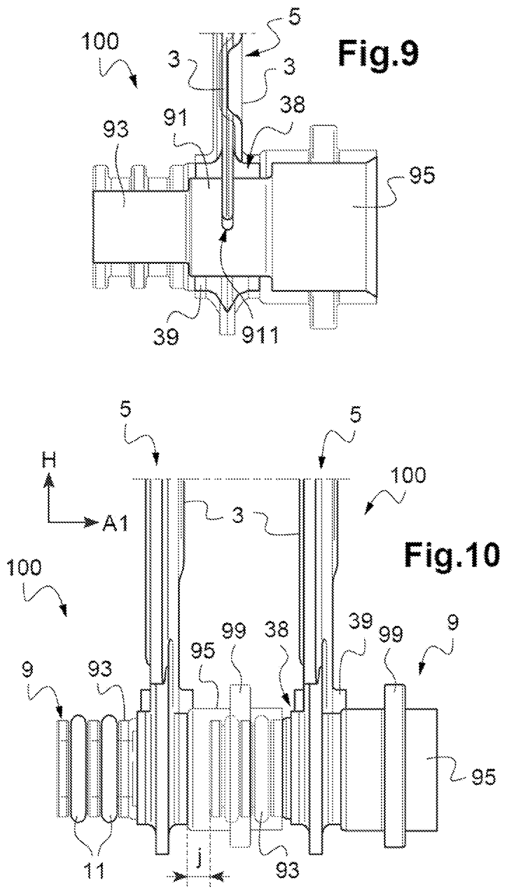

Referring to FIGS. 8 to 10, an intermediate connector 9 is described in more detail. An intermediate connector 9 can be assembled to an associated pair 5 of intermediate plates 3, thus forming an independent thermal regulation sub-assembly 100.

The intermediate connector 9 comprises a distribution zone 91 having at least one slot 911. The distribution zone 91 advantageously has at least two slots 911. The slots 911 open into the heat transfer fluid circulation channel defined by the associated pair 5 of plates 3.

The intermediate connector 9 has a male part 93 on one side and a female part 95 on the other side. The male 93 and female 95 parts are for example arranged on either side of the distribution zone 91.

The male part 93 of the intermediate connector 9 is fitted with at least one seal 11. It can be a compressible seal 11. The seal 11 is for example made of elastomer. It has a shape complementary to the male part 93 that receives it. It can be in particular an O-ring seal 11.

Advantageously, at least two seals 11 are arranged on the male part 93. To this end, the male part 93 has at least one groove, in this case two grooves 931, in which the seals 11 are arranged. Alternatively, a seal with at least two lips can be provided on the male part 93.

The distribution zone 91 and the male 93 and female 95 parts of the connector 9 are advantageously of different sections.

The male part 93 and the distribution zone 91 are dimensioned so as to pass through the openings 38 in the two plates 3 of the associated pair 5. In the assembled state, the distribution zone 91 of the intermediate connector 9 is arranged in the openings 38 in the two plates 3. The collars 39 of the plates 3 are therefore arranged around this distribution zone 91.

By way of example, the female part 95 can have a diameter greater than the diameter of the distribution zone 91. The intermediate connector 9 thus has a shoulder 97 between the distribution zone 91 and the female part 95 configured to come into abutment against the collar 39 of a plate 3 when the intermediate connector 9 is assembled with a pair 5 of plates 3. This ensures the position of the connector 9 relative to the plates 3.

When the intermediate connector 9 is assembled with the associated pair 5 of plates 3, the female part 95 is on one side of the pair 5 of plates 3 while the male part 93 is on the other side of the pair 5 of plates 3.

The male part 93 of the intermediate connector 9 is intended to interact with a complementary female part 95 of another intermediate connector 9 or of an end connector. Likewise, the female part 95 of the intermediate connector 9 is intended to interact with a complementary male part 93 of another intermediate connector 9 or of an end connector. Each male part 93 is intended to be fitted together with a complementary female part 95.

The complementary male 93 and female 95 parts are fitted one inside the other along the stacking axis A1.

The male 93 and female 95 parts are dimensioned such that a male part 93 is fitted together with a female part 95 with an axial clearance j between the end of the female part 95 and the end of the male part 93. The end of the female part 95 is for example defined by the shoulder 97. Along the stacking axis A1, the length of the male part 93 is therefore less than the length of the female part 95. The length of the male part 93 is however chosen to be sufficient to allow the connectors 9 to slide relative to one another and to keep them assembled. Moreover, the male 93 and female 95 parts are dimensioned to make it possible to compress the pairs 5 of plates 3, 3′ after interposition of electronic and/or electrical components.

The length of a male part 93 and the depth of a female part 95 are therefore calculated so that when fitting one into the other, the male part 93 does not come into abutment against the end of the female part 95. This makes it possible, for example, to define a minimum clearance.

Moreover, the male 93 and female 95 parts are advantageously dimensioned such that on assembly, the seals 11 borne by the male part 93 are always inside the female connector 95. A possible margin can be added to this, purely by way of example a margin of around 0.5 mm or 1 mm. This makes it possible to ensure a sufficient sealing area. This makes it possible, for example, to define a maximum clearance.

Moreover, the axial clearance “j” is defined according to the assembly tolerances of the connector 9 in the plate, according to the machining tolerances of the connector 9, and furthermore according to the tolerances of the electronic and/or electrical component, or even of any electrical insulation.

This confers flexibility as regards mounting along the stacking axis A1, during the interposition of an electronic and/or electrical component to be thermally regulated between two pairs 5 of plates 3, and allows compression of the pairs 5 of plates 3 between which the electronic and/or electrical components are intended to be arranged, in order to ensure the thermal contact necessary for thermal regulation, in particular for cooling, of such components.

The intermediate connector 9 further comprises a flange 99. This flange 99 is for example formed around the female part 95. Such a flange 99 is advantageously intended to interact with an assembly tool, for fitting together two complementary connectors. The flange 99 has in this example a generally annular shape.

The flange 99 advantageously has a poka-yoke surface 991. This makes it possible to ensure that the connector 9 is mounted in a specific position, in particular prior to brazing with the associated pair 5 of plates 3. The poka-yoke surface 991 can, purely as an example, take the form of a flat surface.

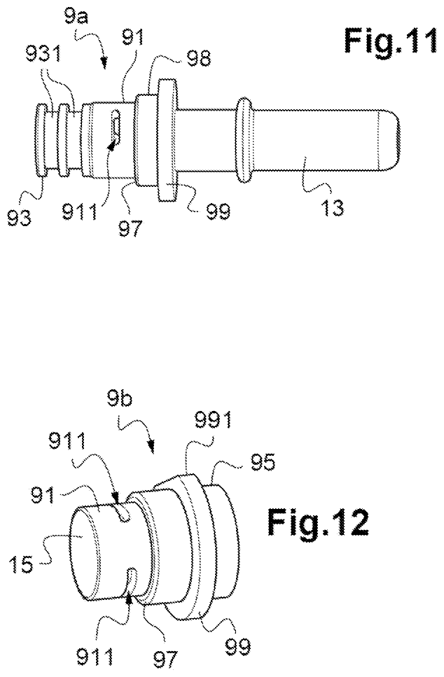

Exemplary embodiments of the end connectors 9a, 9b, 9c, 9d are described in more detail with reference to FIGS. 11 to 15.

The end connectors 9a, 9b, 9c, 9d respectively comprise a distribution zone 91 having at least one slot 911, preferably at least two slots 911. The distribution zone 91 of an end connector 9a, 9b, 9c, 9d can be as defined above for an intermediate connector 9. The distribution zones 91 of all the connectors 9, 9a, 9b, 9c, 9d can be identical.

The slots 911 in the connectors 9, 9a, 9b, 9c, 9d opening into the heat transfer fluid circulation channels defined by the pairs 5 of plates 3, 3′, are calibrated, dimensioned, to ensure an optimized distribution in all the heat transfer fluid circulation channels. To this end, the two slots 911 of each distribution zone 91 can be dimensioned such that the ratio of the total section for passage of the fluid through the two slots 911 to the total section for passage in the heat transfer fluid manifold is between 12% and 25%, in particular between 16% and 21%.

When the connectors 9, 9a, 9b, 9c, 9d are generally cylindrical in shape, the slots 911 can extend over a circumference of the distribution zone 91 over a cumulative angle between 30° and 180°.

Furthermore, unlike the intermediate connector 9 described above, the end connectors 9a, 9b, 9c, 9d do not include both a male part 93 and a female part 95. Each end connector 9a, 9b, 9c, 9d comprises one or the other, i.e. either a male part 93 or a female part 95.

Referring also to FIG. 1, at least one of the manifolds 7, according to the embodiment described each manifold 7, for heat transfer fluid, comprises a first end connector 9a, respectively 9d, comprising a male part 93 and a second end connector 9b, respectively 9c, comprising a female part 95.

The male 93 and female 95 parts are produced in accordance with the above description relating to the intermediate connector 9. Thus, all the male parts 93 of the connectors 9, 9a, 9d are identical. All the female parts 95 of the connectors 9, 9b, 9c are identical. The above description of the male 93 and female 95 parts, as well as of the axial clearance on fitting together, therefore applies to the respective male 93 and female 95 parts of the end connectors 9, 9a, 9b, 9c, 9d.

Each male part 93 is intended to be fitted together with a complementary female part 95. The male part 93 of the first end connector 9a, respectively 9d, is intended to interact with a complementary female part 95 of another connector, which can be an intermediate connector 9 or the second end connector 9b, respectively 9c. Likewise, the female part 95 of the second end connector 9b, respectively 9c, is intended to interact with a complementary male part 93 of another connector, which can be an intermediate connector 9 or the first end connector 9a, respectively 9d.

As described above, a male part 93 of a connector 9, 9a, 9d is intended to be fitted together with a female part 95 of a connector 9, 9b, 9c, with an axial clearance between the end of the female part 95 and the end of the male part 93, making it possible to slide the connectors 9, 9a, 9b, 9c, 9d along the stacking axis A1, and to compress the pairs 5 of plates 3, 3′ between which the electronic and/or electrical components are intended to be arranged.

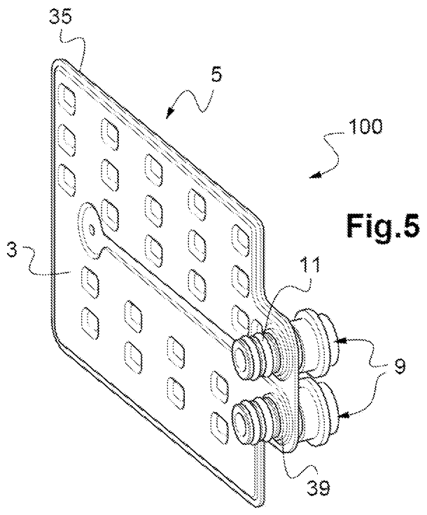

At least one seal 11 as described above, with reference to FIGS. 4 and 5, is also arranged on the male part 93 of the first end connector 9a, respectively 9d.

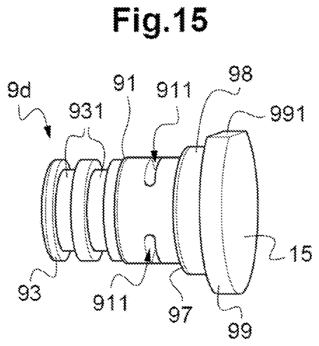

Furthermore, in order to ensure the position, with respect to the end plate 3′, of the first end connector 9a (FIG. 11), respectively 9d (FIG. 15), having the male part 93 but not having a female part, this first end connector 9a, respectively 9d, can include a shoulder 97 as described above between the distribution zone 91 and a positioning section 98 of diameter greater than the diameter of the distribution zone 91 configured to come into abutment against the collar 39 of the end plate 3′.

The various thermal regulation sub-assemblies 100, 200, 300 of FIGS. 5 to 7 can thus be mechanically assembled by fitting together the connectors 9, 9a, 9b, 9c, 9d described with reference to FIGS. 8 to 15, for example at ambient temperature, while ensuring sealing between the connectors 9, 9a, 9b, 9c, 9d by virtue of the interposition of the seals 11 added to the male parts 93 of the connectors 9, 9a, 9d, which seals are compressed by the complementary female parts 95 of the connectors 9, 9b, 9c, on assembly.

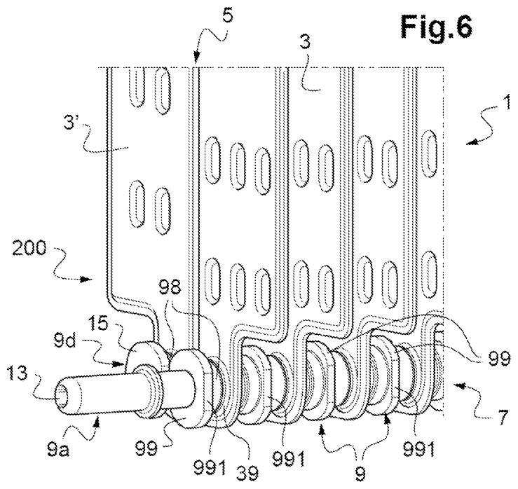

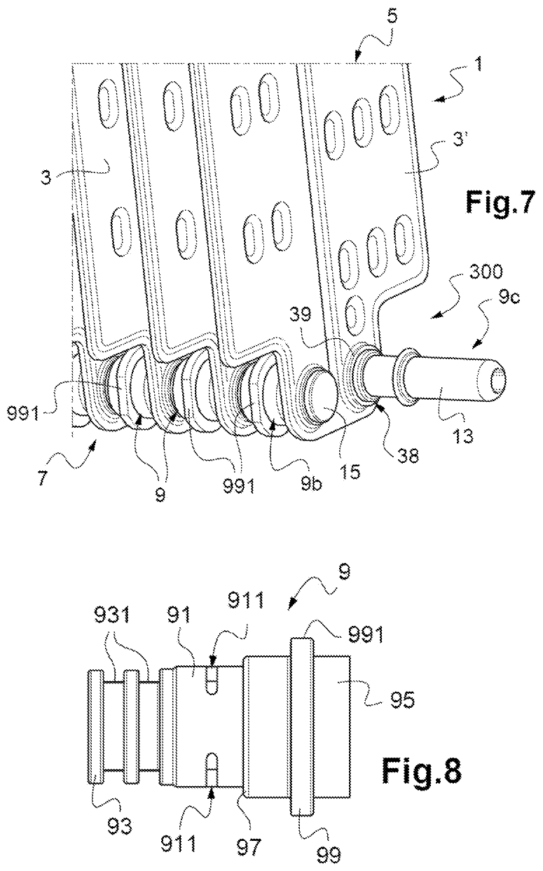

Moreover, one of the end connectors defining a heat transfer fluid manifold 7 (see FIGS. 6, 7) is configured to be connected to a heat transfer fluid circuit. At least one connection member 13 for connection to the heat transfer fluid circuit is provided for this purpose at the end of at least one, in this case each, heat transfer fluid manifold 7, to ensure the connection between the thermal regulation device 1 and the heat transfer fluid circuit. The connection member 13 can have a generally hollow shape, such as a cylindrical shape. In the assembled state, the connection member 13 extends from an end plate 3′ on the opposite side to the stack of the thermal regulation device 1.

Such a connection member 13 is advantageously formed or made in one piece with an end connector.

According to the embodiment shown in FIGS. 6 and 7, the first end connector 9a partially defining one of the heat transfer fluid manifolds 7, in particular with the second end connector 9b, can have such a connection member 13. Likewise, the second end connector 9c partially defining the other heat transfer fluid manifold 7, in particular with the first end connector 9d, can have such a connection member 13.

With reference to FIGS. 11, and 13, 14, the connection member 13 can be formed on an end connector having a male part 93 or on the contrary a female part 95. In this case, the connection member 13 is arranged on the other side of the distribution zone 91 which is opposite the side with the male 93 or female 95 part.

In the example of FIG. 11, the first end connector 9a comprises the distribution zone 91, the male part 93 on one side of the distribution zone 91, and on the other side, the connection member 13.

Moreover, the first end connector 9a can comprise a flange 99, as defined above, arranged between the connection member 13 and the distribution zone 91, or the positioning section 98. This flange 99 also facilitates assembly of the first end connector 9a.

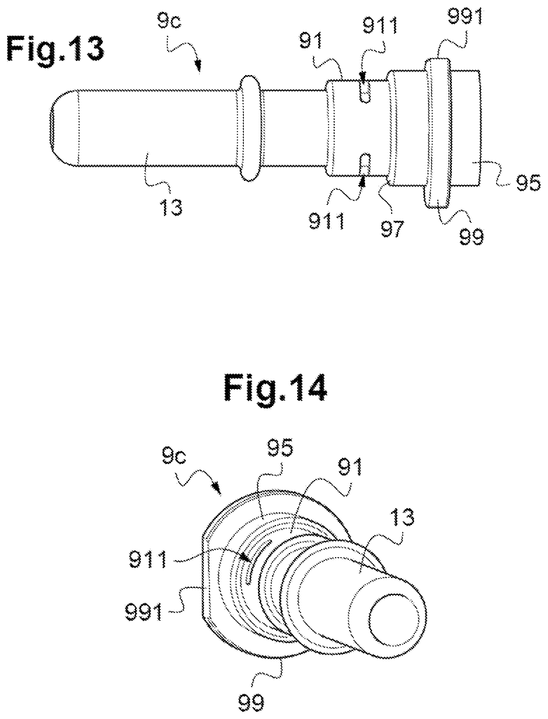

In the example of FIGS. 13 and 14, the second end connector 9c comprises the distribution zone 91, the female part 95 on one side of the distribution zone 91, and on the other side, the connection member 13.

The other end connector defining a manifold 7 which is not provided with such a connection member 13, is closed off on one side, more specifically on the side opposite the stack of the thermal regulation device 1, as can be seen more clearly in FIGS. 1, 6 and 7. This end connector can include a blind wall 15 for this purpose. The blind wall 15 closes off an opening 38 in the end plate 3′ when the end connector is assembled with this end plate 3′. According to an alternative not shown, it could possibly be envisaged that the end connector be closed off by the end plate 3′, which would not have an opening.

According to the embodiment shown in FIGS. 6 and 7, it is either the second end connector 9b partially defining one of the heat transfer fluid manifolds 7, in particular with the first end connector 9a, or the first end connector 9d partially defining the other heat transfer fluid manifold 7, in particular with the second end connector 9c.

With reference to FIGS. 12 and 15, it can be an end connector having a male part 93 or on the contrary a female part 95. In this case, it is closed off on the side of the distribution zone 91 which is opposite the side with the male 93 or female 95 part.

In the example of FIG. 12, the second end connector 9b comprises the distribution zone 91, the female part 95 on one side of the distribution zone 91, and on the other side, the blind wall 15.

In the example of FIG. 15, the first end connector 9d comprises the distribution zone 91, the male part 93 on one side of the distribution zone 91, and on the other side, the blind wall 15.

Moreover, this first end connector 9d can include a flange 99, as defined above. The blind wall 15 can be arranged so as to close off the flange 99. In this example, the positioning section 98 is arranged between the flange 99 and the distribution zone 91. This flange 99 also facilitates assembly of the first end connector 9d.

Thus, with reference to FIGS. 6 and 7, all the connectors 9, 9a, 9b, 9c, 9d, even without a female part, can have such a flange 99. On assembly, the poka-yoke surfaces 991 of all of the connectors 9 and 9a, 9b, or 9c, 9d, defining a heat transfer fluid manifold 7 are all arranged on the same side of the thermal regulation device 1.

With reference to all the figures, the thermal regulation device 1 as described above can be assembled according to an assembly method comprising the steps described below.

A predefined number of plates 3, 3′, including two end plates 3′, can be assembled so as to form at least two pairs 5 of plates 3, 3′, each pair 5 defining between them a heat transfer fluid circulation channel.

At least one connector 9, 9a, 9b, 9c, 9d can then be assembled to each pair 5 of plates 3, 3′.

In particular, at least one first end connector 9a, respectively 9d, can be assembled to a pair 5 comprising an end plate 3′, and at least one second end connector 9b, respectively 9c, can be assembled to a pair 5 including another end plate 3′. Depending on the number of plates 3, 3′, in other words if the thermal regulation device 1 comprises more than two pairs 5 of plates 3, 3′, at least one intermediate connector 9 can be assembled to a pair 5 of intermediate plates 3.

According to the embodiment described, two connectors 9, 9a, 9b, 9c, 9d can be assembled to the same associated pair 5 of plates 3, 3′. Thus, two end connectors 9a and 9d, respective 9b and 9c, can be assembled to the same associated pair 5 of plates 3, 3′. If more than two pairs 5 of plates 3, 3′ are provided, two intermediate connectors 9 can be assembled to the same associated pair 5 of intermediate plates 3.

The slot or slots 911 in the distribution zone 91 of each connector 9, 9a, 9b, 9c, 9d open into the heat transfer fluid circulation channel defined by the associated pair 5 of plates 3, 3′.

The connectors 9, 9a, 9b, 9c, 9d are assembled to an associated pair 5 of plates 3, 3′ for example by brazing.

At least one seal 11, preferably two seals 11, can be arranged on the male parts 93 of the connectors, in particular the first end connectors 9a, 9d, and any intermediate connector or connectors 9.

Various thermal regulation sub-assemblies 100, 200, 300 are obtained. Such independent sub-assemblies 100, 200, 300 can be delivered for example to a car manufacturer for final assembly. Alternatively, they can be assembled together before being delivered for final assembly with the electronic and/or electrical component or components liable to generate heat during operation.

The thermal regulation sub-assemblies 100, 200, 300 can be assembled via their connectors 9, 9a, 9b, 9c, 9d, by fitting together the male 93 and female 95 parts of the connectors of the adjacent pairs 5 of plates 3, 3′. The connector 9, 9a, 9b, 9c, 9d assembly step is a mechanical assembly step. Such a mechanical assembly step can be carried out at ambient temperature, unlike a step of assembly by brazing involving passing through a furnace.

The thermal regulation device 1 thus obtained comprises at least two pairs 5 of plates 3, 3′ assembled to the manifolds 7, in particular a plurality of pairs 5 of plates 3, 3′, and has the general shape of a comb. The pairs 5 of plates 3, 3′ of the thermal regulation device 1 are advantageously spaced apart along the stacking axis A1, by a predefined gap, which can be standard.

The method does not include a step of brazing the whole of the thermal regulation device 1 thus obtained. The function of sealing is not intended to be ensured by brazing.

The seals 11 once assembled to the thermal regulation device 1 remain separate parts, not irreversibly connected to the plates 3, 3′, even after assembly of the thermal regulation sub-assemblies 100, 200, 300.

The electronic and/or electrical component or components can be interposed in the thermal regulation device 1 obtained according to this assembly method, in order to form an electrical module, for example to be mounted in a motor vehicle.

The electronic and/or electrical components can be inserted simultaneously, or alternatively one by one, between the pairs 5 of plates 3, 3′. To facilitate this insertion, the predefined gap between the pairs 5 of plates 3, 3′ can be greater than the dimension of said components along the stacking axis A1. Optionally, if the gap between the pairs 5 of plates 3, 3′ is not sufficient to allow the insertion of the electronic and/or electrical components, the pairs 5 of plates 3, 3′ can be moved apart or away from each other along the stacking axis A1 by sliding the connectors 9, 9a, 9b, 9c, 9d. After insertion, the assembly can be compressed along the stacking axis A1, preferably on both sides of the thermal regulation device 1.

Thus, the complementary hollow connectors 9, 9a, 9b, 9c, 9d defining the heat transfer fluid manifolds 7, by being fitted one inside the other, offer mounting flexibility in the direction of stacking of the pairs 5 of plates 3, 3′, which makes it possible to compress the assembly, when the components are inserted between the pairs 5 of plates 3, 3′, to ensure that the components are held in position by the pairs 5 of plates 3, 3′, and ensure the thermal contact necessary for thermal regulation, such as cooling, of the components.

In operation, the thermal regulation device 1 is supplied with heat transfer fluid via a heat transfer fluid inlet manifold 7, and the heat transfer fluid is distributed into each heat transfer fluid circulation channel via the slots 911 in one or each connector 9, 9a, 9b, 9c, 9d defining this heat transfer fluid inlet manifold 7, then the heat transfer fluid is discharged from the heat transfer fluid circulation channel via the slots 911 in another connector 9, 9a, 9b, 9c, 9d this time defining the heat transfer fluid outlet manifold 7.

Sealing is ensured at the connectors 9, 9a, 9b, 9c, 9d defining the heat transfer fluid manifolds 7 thanks to the seals 11 fitted to the male parts 93, while making it possible to compress the pairs 5 of plates 3, 3′ on the components upon final assembly.

What is claimed is:

1. A thermal regulation device for at least one electronic and/or electrical component, in particular for a motor vehicle, said thermal regulation device comprising:
a stack of at least two pairs of plates, with a space between the pairs for at least one component electronic and/or electrical each pair of plates defining a heat transfer fluid circulation channel, and
at least one heat transfer fluid manifold, in fluidic communication with the heat transfer fluid circulation channels defined by the pairs of plates,
wherein said at least one heat transfer fluid manifold includes at least two complementary hollow connectors, such that:
each connector is assembled to an associated pair of plates and includes a distribution zone having at least one first slot opening into the heat transfer fluid circulation channel defined by the pair of plates, and
the connectors assembled to two adjacent pairs of plates include complementary male and female parts, fitted one inside the other, the male part bearing at least one first seal.

2. The thermal regulation device as claimed in claim 1, wherein said at least one heat transfer fluid manifold includes two end connectors, including a first end connector including a male part and a second end connector including a female part, one of the end connectors being configured to be connected to a heat transfer fluid circuit, the other end connector being closed off on a side opposite the stack of plates.

3. The thermal regulation device as claimed in claim 1, including at least one pair of intermediate plates between two end plates, assembled with an intermediate connector including on one side a male part and on the other side a female part.

4. The thermal regulation device as claimed in claim 1, wherein the plates are arranged along a stacking axis and wherein the complementary male and female parts of the connectors are fitted one inside the other along the stacking axis with an axial clearance between the end of the female part and the end of the male part.

5. The thermal regulation device as claimed in claim 1, wherein the connectors respectively have at least one second slot opening into the heat transfer fluid circulation channel defined by the associated pair of plates.

6. The thermal regulation device as claimed in claim 5, wherein the at least one first slot and the at least one second slot are dimensioned such that the ratio of the total section for passage of the heat transfer fluid through the at least one first slot and the at least one second slot in the connector to the section for passage of the heat transfer fluid in the heat transfer fluid manifold is between 12% and 25%, in particular between 16% and 21%.

7. The thermal regulation device as claimed in claim 1, wherein the male part bears at least one second seal.

8. The thermal regulation device as claimed in claim 1, wherein the connectors respectively have a flange.

9. The thermal regulation device as claimed in claim 1, wherein the plates each have at least one opening, and wherein the connectors are assembled to the pairs of plates such that the distribution zone of each connector is arranged at the openings in the plates of an associated pair.

10. A method for assembling a thermal regulation device for at least one electronic and/or electrical component, in particular for a motor vehicle, said thermal regulation device including:
a stack of at least two pairs of plates, with a space between the pairs for at least one component electronic and/or electrical, each pair of plates defining a heat transfer fluid circulation channel, and
at least one heat transfer fluid manifold, in fluidic communication with the heat transfer fluid circulation channels defined by the pairs of plates,
wherein said at least one heat transfer fluid manifold includes at least two complementary hollow connectors, such that:
each connector is assembled to an associated pair of plates and includes a distribution zone having at least one first slot opening into the heat transfer fluid circulation channel defined by the pair of plates, and
the connectors assembled to two adjacent pairs of plates include complementary male and female parts, fitted one inside the other, the male part bearing at least one first seal;
said method comprising:
assembling the at least two pairs of plates defining between them the heat transfer fluid circulation channel,
assembling at least a first connector to a first associated pair of plates and a second connector to a second associated pair of plates, such that said at least one first slot in the distribution zone of each connector opens into the heat transfer fluid circulation channel defined by the associated pair of plates,
arranging at least one first seal on the male part of at least one of the connectors, and
assembling the connectors by fitting together the male and female parts of the connectors of the adjacent pairs of plates.

11. The thermal regulation device as claimed in claim 6, wherein the ratio of the total section for passage of the heat transfer fluid is between 16% and 21%.
